(19) United States
(12) Patent Application Publication
(10) Pub. No.: US 2026/0239926 A1
(43) Pub. Date: Aug. 13, 2026

(54) METHODS AND MECHANISMS FOR USING MACHINE LEARNING TO GENERATE DIAGNOSTIC REPORTS BASED ON ANOMALOUS DATA

(71) Applicant: Applied Materials, Inc., Santa Clara, CA (US)

(72) Inventors: Peter J. Lindner, Saratoga Springs, NY (US); Michael Hotaling, Latham, NY (US); Jimmy Iskandar, Fremont, CA (US); Arvind Shankar Raman, Austin, TX (US); Michael D. Armacost, San Jose, CA (US)

(21) Appl. No.: 19/052,789

(22) Filed: Feb. 13, 2025

(51) Int. Cl. H01L 21/66

(52) U.S. Cl. CPC H10P 74/00

(57) ABSTRACT

A system configured to detect, by a processing device, an anomaly that occurred during a manufacturing process performed by a substrate processing system. A set of prompts is generated based on the anomaly. Each prompt is correlated to specific data obtained from one or more datastores. For each prompt, a respective output of the first trained machine learning model is obtained and a structured prompt is generated based on respective outputs. The structured prompt is provided as input to a second trained machine learning model an output of the second trained machine learning model is obtained. The output of the second trained machine learning model comprising a diagnostic report associated with the anomaly.

### TECHNICAL FIELD

The present disclosure relates to methods and mechanisms for using machine learning to generate diagnostic reports based on anomalous data.

### BACKGROUND

Manufacturing of modern materials often involves various deposition techniques, such as chemical vapor deposition (CVD) or physical vapor deposition (PVD) techniques, in which atoms or molecules of one or more selected types are deposited on a semiconductor device (e.g., a substrate) held in low or high vacuum environments that are provided by vacuum processing (e.g., deposition, etching, etc.) chambers. Materials manufactured in this manner can include monocrystals, semiconductor films, fine coatings, and numerous other substances used in practical applications, such as electronic device manufacturing. Many of these applications depend on the purity and specifications of the materials grown in the processing chambers. The quality of such materials, in turn, depend on adherence of the manufacturing operations to correct process specifications. To maintain isolation of the inter-chamber environment and to minimize exposure of substrates to ambient atmosphere and contaminants, various sensor detection techniques are used to monitor processing chamber environment, substrate transportation, physical and chemical properties of the products, and the like to detect potential anomalies and issues. Improving precision, reliability, and efficiency of such monitoring presents a number of technological challenges that impede progress of electronic device manufacturing and negatively impact the quality of the products of semiconductor device manufacturing.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, a system is configured to detect, by a processing device, an anomaly that occurred during a manufacturing process performed by a substrate processing system. A set of prompts is generated based on the anomaly. Each prompt is correlated to specific data obtained from one or more datastores. For each prompt, a respective output of the first trained machine learning model is obtained and a structured prompt is generated based on respective outputs. The structured prompt is provided as input to a second trained machine learning model an output of the second trained machine learning model is obtained. The output of the second trained machine learning model comprising a diagnostic report associated with the anomaly.

A further aspect of the disclosure includes a method according to any aspect or implementation described herein.

A further aspect of the disclosure includes a non-transitory computer-readable storage medium comprising instructions that, when executed by a processing device operatively coupled to a memory, performs operations according to any aspect or implementation described herein.

### BRIEF DESCRIPTION OF THE DRAWINGS

The present disclosure is illustrated by way of example, and not by way of limitation in the figures of the accompanying drawings.

FIG. 1 is a block diagram illustrating an example system architecture, in accordance with some implementations of the present disclosure.

FIG. 2 is a top schematic view of an example manufacturing system, in accordance with some implementations of the present disclosure.

FIG. 3 is a block diagram illustrating an example predictive architecture, in accordance with some implementations of the present disclosure.

FIG. 4 is a flow diagram of a framework for applying a machine learning model to generate a diagnostic report, in accordance with some implementations of the present disclosure.

FIG. 5 is a flow diagram of method for generating a diagnostic report, in accordance with some implementations of the present disclosure.

FIG. 6 is a block diagram illustrating a computer system, according to certain implementations.

### DETAILED DESCRIPTION

Described herein are technologies directed to methods and mechanisms for using machine learning to generate diagnostic reports based on anomalous data. Semiconductor device manufacturing systems typically include multiple process chambers where each process chamber can have multiple sub-systems operating during each substrate manufacturing process (e.g., the deposition process, the etch process, the polishing process, etc.). A sub-system can be characterized as a set of sensors and controls related with an operational parameter of the process chamber. An operational parameter can be a temperature, a flow rate, a pressure, and so forth. In an example, a pressure sub-system can be characterized by one or more sensors measuring the gas flow, the chamber pressure, the control valve angle, the foreline (vacuum line between pumps) pressure, the pump speed, and so forth. Accordingly, the process chamber can include a pressure sub-system, a flow sub-system, a temperature subsystem, and so forth.

A process chamber can perform each substrate manufacturing process according to a process recipe. A process recipe defines a particular set of operations to be performed for the substrate during the process and can include one or more settings associated with each operation. A process recipe can be embodied as a table of recipe settings including a set of inputs or recipe parameters (“parameters”) and processes that are manually entered by a user (e.g., process engineer) to achieve a set of target properties (e.g., on-substrate characteristics), also referred to as a set of goals. For example, a deposition process recipe can include a temperature setting for the process chamber, a pressure setting for the process chamber, a flow rate setting for a precursor for a material included in the film deposited on the substrate surface, etc. Accordingly, the thickness of each film layer, the depth of each etch, and so forth, can be correlated to these process chamber settings.

Typical semiconductor device manufacturing processes often require tens or hundreds of steps, e.g., introducing a gas into a processing chamber, heating the chamber environment, changing a composition of gas, purging a chamber, pumping the gas out, changing pressure, moving a substrate from one position to another, creating or adjusting a plasma environment, performing etching or deposition steps, and so on. The very complexity of the semiconductor manufacturing technology requires processing a constant stream of run-time data from various sensors placed inside the manufacturing system. Such sensor can include temperature sensors, pressure sensors, chemical sensors, gas flow sensors, motion sensors, position sensor, optical sensors, and other types of sensors. The manufacturing system can have multiple sensors of the same (or similar) type distributed throughout various parts of the system. For example, a single processing chamber can have multiple chemical sensors to detect concentration of chemical vapor at various locations within the processing chamber and can similarly have multiple temperature sensors to monitor a temperature distribution. Some or all of the sensors can output a constant stream of data. For example, a temperature sensor can output a temperature reading ever second (or more frequently) so that a single etching step that takes several minutes to perform can be generate hundreds of data points (referred to as trace data) from this sensor alone.

Each sensor (alone or in combination with other sensors) can output data that is indicative of a sudden or gradual detrimental changes in the environment or in the settings of the manufacturing process. These sensed changes can be referred to as “anomalies” and can reflect certain distinct behavior, such as component deteriorations, output variations, contaminations, component failures, user errors, etc. Anomaly detection systems can be used to read sensor data and identity anonymous data by monitoring whether the manufacturing process conforms to the process specifications. These detection systems typically indicate which sensor or recipe step includes the anomaly but may fail to identify the type of issue that occurred, the potential root cause of the issue, the least invasive or least expensive action to perform to correct the issue, etc. As such, performing diagnostics (e.g., identifying the root cause, identifying an appropriate corrective action, etc.) is typically done in an ad-hoc manner using simple trial and error techniques performed by technicians. Thus, current diagnostics procedures are ineffective and time consuming since they are based on trial and error of respective technicians. This can cause the manufacturing equipment to experience extended downtime while trial and error is performed, thus reducing the yield of the manufacturing equipment.

Aspects and implementations of the present disclosure address these and other shortcomings of the existing technology by using machine learning to generate diagnostic reports based on anomalous data. In particular, the implementations of the present disclosure can use a machine learning model to generate a diagnostic report that can identify and/or classify one or more possible issues related to anomalous data obtained from a manufacturing system. Further, the implementations disclosed can provide a list of corrective actions that can be performed to correct the issues identified in the diagnostic report.

The system of the present disclosure can monitor a manufacturing process for anomalies. In response to detecting an anomaly during the manufacturing process (e.g., identifying anomalous data using an anomaly detection technique), the system of the present disclosure can automatically generate a set of prompts (e.g., questions or statements) related to the anomaly. The set of prompts can be generated based on, for example, the type of anomaly, the sub-system type that generated the anomaly, the sensor type related to the anomaly, a predetermined listing, etc. Each prompt from the set can be correlated to a corresponding database of specific-knowledge data. Specific-knowledge data can include unique, valuable, and/or proprietary data related to certain topics, items, and/or organizations (e.g., data from research papers, technical support tickets, user manuals, tech bulletins, service cases, reports, transcripts, guides, technical libraries, and so forth). Each of the prompts and the specific-knowledge data from the corresponding database can then be individually provided as input into a machine-learning model, such as a large language model (LLM) designed to understand and generate human-like text. For each input, the LLM can generate, as output, a respective knowledge-based report. The knowledge-based reports can include predictive data indicative of one or more answers to the respective prompt in view of the retrieved specific-knowledge data (e.g., source informed answers).

The knowledge-based reports can be organized into a single prompt having a specified structure to enhance coherence and relevance. This structured prompt can include one or more of a tasks, one or more instructions, a request for a desired format, data from the knowledge-based reports, etc. The structured prompt can then be provided, as input, to the LLM (or a different LLM) which can then generate a diagnostic report for the anomaly. In an illustrative example, the diagnostic report can include a problem statement, a scrubbed plot (e.g., no axis, no customer intellectual property, etc.) of the sensor data related to the anomaly, predictive data identifying the issue, one or more recommendations (e.g., a recommended corrective action), one or more recent actions performed to address the identified anomaly, and a listing of similar anomalies. The diagnostic report can then be sent to a client device for access by, for example, a technician that maintains the manufacturing equipment.

Aspects of the present disclosure result in technological advantages of improving the accuracy and speed of diagnostic techniques during a manufacturing process. Aspects of the present disclosure further enable the identification of appropriate corrective actions for a particular anomaly. This allows the users of the manufacturing system to correct the related issue, thus saving considerable costs and preventing unscheduled and lengthy downtime related to troubleshooting during maintenance.

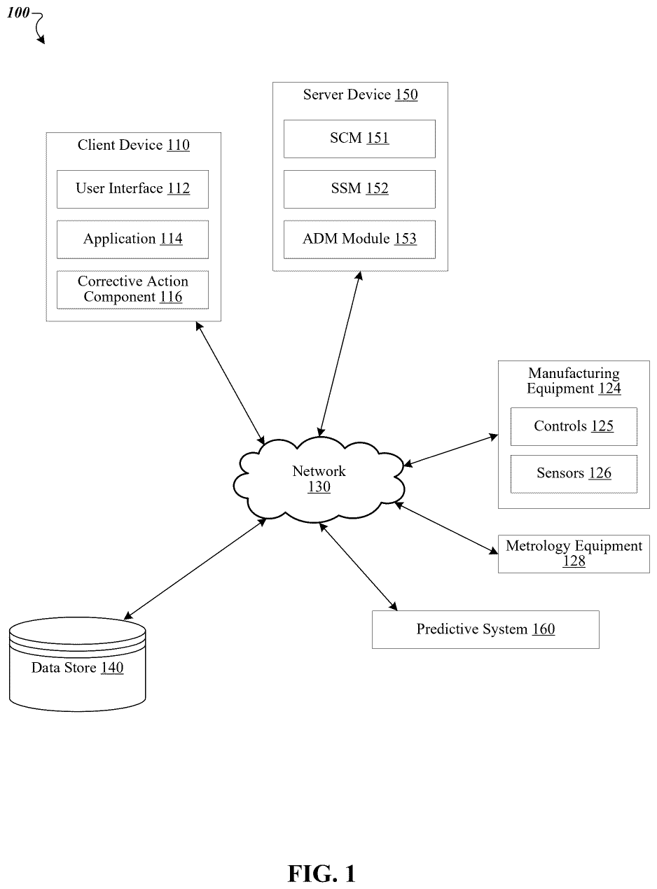

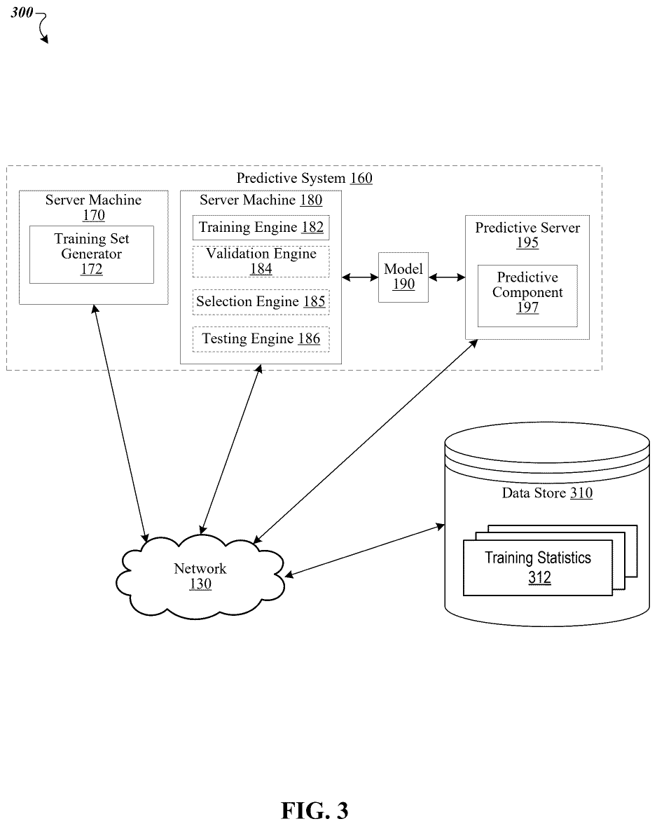

FIG. 1 depicts an illustrative computer system architecture 100, according to aspects of the present disclosure. In some implementations, computer system architecture 100 can be included as part of a manufacturing system for processing substrates. Computer system architecture 100 includes a client device 110, manufacturing equipment 124, metrology equipment 128, predictive system 160 (e.g., to generate predictive data, to provide model adaptation and modification, to use a knowledge base, etc., which will be described in detail in FIG. 3), data store 140, and server device 150. The manufacturing equipment 124 can include sensors 126 configured to capture data for a substrate being processed at the manufacturing system. In some implementations, the manufacturing equipment 124 and sensors 126 can be part of a sensor system that includes a sensor server (e.g., field service server (FSS)) and sensor identifier reader (e.g., front opening unified pod (FOUP) radio frequency identification (RFID) reader for sensor system). In some implementations, metrology equipment 128 can be part of computer system architecture 100 that includes a metrology server (e.g., a metrology database, metrology folders, etc.) and metrology identifier reader (e.g., FOUP RFID reader for metrology system).

Manufacturing equipment 124 can produce products, such as electronic devices, following a recipe or performing runs over a period of time. Manufacturing equipment 124 can include a process chamber. Manufacturing equipment 124 can perform a process for a substrate (e.g., a wafer, etc.) at the process chamber. Examples of substrate processes include a deposition process to deposit one or more layers of film on a surface of the substrate, an etch process to form a pattern on the surface of the substrate, etc. Manufacturing equipment 124 can perform each process according to a process recipe. A process recipe defines a particular set of operations to be performed for the substrate during the process and can include one or more settings associated with each operation. For example, a deposition process recipe can include a temperature setting for the process chamber, a pressure setting for the process chamber, a flow rate setting for a precursor for a material included in the film deposited on the substrate surface, etc.

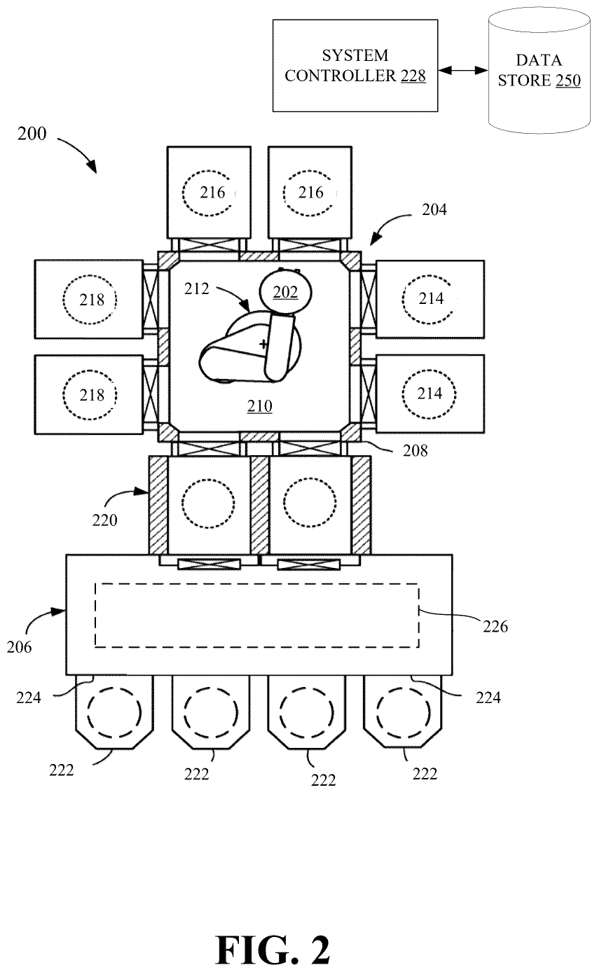

In some implementations, manufacturing equipment 124 includes sensors 126 that are configured to generate data associated with a substrate processed at manufacturing system 100. For example, a process chamber can include one or more sensors configured to generate spectral or non-spectral data associated with the substrate before, during, and/or after a process (e.g., a deposition process, an etch process, etc.) is performed for the substrate. In some implementations, spectral data generated by sensors 126 can indicate a concentration of one or more materials deposited on a surface of a substrate. Sensors 126 configured to generate spectral data associated with a substrate can include reflectometry sensors, ellipsometry sensors, thermal spectra sensors, capacitive sensors, and so forth. Sensors 126 configured to generate non-spectral data associated with a substrate can include temperature sensors, pressure sensors, flow rate sensors, voltage sensors, etc. For example, each sensor 126 can be a temperature sensor, a pressure sensor, a chemical detection sensor, a chemical composition sensor, a gas flow sensor, a motion sensor, a position sensor, an optical sensor, or any and other type of sensors. Some or all of the sensors 126 can include a light source to produce light (or any other electromagnetic radiation), direct it towards a target, such as a component of the machine 100 or a substrate, a film deposited on the substrate, etc., and detect light reflected from the target. The sensors 126 can be located anywhere inside the manufacturing equipment 124 (for example, within any of the chambers including the loading stations, on one or more robots, on a robot blade, between the chambers, and so one), or even outside the manufacturing equipment 124 (where the sensors can test ambient temperature, pressure, gas concentration, and so on). Further details regarding manufacturing equipment 124 are provided with respect to FIG. 2.

In some implementations, sensors 126 provide sensor data (e.g., sensor values, features, trace data) associated with manufacturing equipment 124 (e.g., associated with producing, by manufacturing equipment 124, corresponding products, such as substrates). The manufacturing equipment 124 can produce products following a recipe or by performing runs over a period of time. Sensor data received over a period of time (e.g., corresponding to at least part of a recipe or run) can be referred to as trace data (e.g., historical trace data, current trace data, etc.) received from different sensors 126 over time. Sensor data can include a value of one or more of temperature (e.g., heater temperature), spacing (SP), pressure, high frequency radio frequency (HFRF), voltage of electrostatic chuck (ESC), electrical current, material flow, power, voltage, etc. Sensor data can be associated with or indicative of manufacturing parameters such as hardware parameters, such as settings or components (e.g., size, type, etc.) of the manufacturing equipment 124, or process parameters of the manufacturing equipment 124. The sensor data can be provided while the manufacturing equipment 124 is performing manufacturing processes (e.g., equipment readings when processing products). The sensor data can be different for each substrate.

In some implementations, manufacturing equipment 124 can include controls 125. Controls 125 can include one or more components or sub-systems configured to enable and/or control one or more processes of manufacturing equipment 124. For example, a sub-system can include a pressure sub-system, a flow sub-system, a temperature sub-system and so forth, each sub-system having one or more components. The component can include, for example, a pressure pump, a vacuum, a gas deliver line, a plasma etcher, actuators etc. In some implementations, controls 125 can be managed based on data from sensors 126.

In some implementations, certain sensors 126 and controls 125 can be related to one or more control modules. In particular, each control module can include a set of sensors 126, controls 125, control logic regulating the sensors and/or components, etc. In an illustrative example, the controls modules can include a thermal control module, a plasma control module, a reactant flux control module, and a substrate control module. The thermal control module can include sensors and controls related to providing and maintain a heating environment in a process chamber (e.g., heater, heater sensor, etc.). The plasma control module can include sensors and controls related to creating or adjusting a plasma environment in a process chamber (e.g., plasma etcher, etcher sensor, etc.). The reactant flux control module can include sensors and controls related to the gas flow operations in a process chamber (e.g., gas flow control and sensor, pump, etc.). The substrate control module can include sensors and controls related to substrate properties (e.g., warp experience by a substrate). In certain implementations, sensor data from one or more of the particular control modules can be processed and analyzed, via modules 151-153 and the methods discussed herein, to control the respective operating conditions (e.g., a parameter of a process recipe) associated with said process control module.

Metrology equipment 128 can provide metrology data associated with substrates processed by manufacturing equipment 124. The metrology data can include a value of film property data (e.g., wafer spatial film properties), dimensions (e.g., thickness, height, etc.), dielectric constant, dopant concentration, density, defects, etc. In some implementations, the metrology data can further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data can be of a finished or semi-finished product. The metrology data can be different for each substrate. Metrology data can be generated using, for example, reflectometry techniques, ellipsometry techniques, TEM techniques, and so forth.

In some implementations, metrology equipment 128 can be included as part of the manufacturing equipment 124. For example, metrology equipment 128 can be included inside of or coupled to a process chamber and configured to generate metrology data for a substrate before, during, and/or after a process (e.g., a deposition process, an etch process, etc.) while the substrate remains in the process chamber. In some instances, metrology equipment 128 can be referred to as in-situ metrology equipment. In another example, metrology equipment 128 can be coupled to another station of manufacturing equipment 124. For example, metrology equipment can be coupled to a transfer chamber, such as transfer chamber 210 of FIG. 2, a load lock, such as load lock 220, or a factory interface, such as factory interface 206.

The client device 110 can include a computing device such as personal computers (PCs), laptops, mobile phones, smart phones, tablet computers, netbook computers, network connected televisions (“smart TVs”), network-connected media players (e.g., Blu-ray player), a set-top box, over-the-top (OTT) streaming devices, operator boxes, etc. Client device 110 can display a user interface 112, such as a graphical user interface, application 114, and corrective action component 116. In some implementations, client device 110 can provide, for display on user interface 112, sensor data, predictive data (e.g., data from predictive system 160, such as, for example, a diagnostic report), server data (e.g., any data generated and/or provided by server device 110), or any other data items. In some implementations, user interface 112 can enable the user to provide, as input, data, commands, etc. In some implementations, user interface 112 can be presented via a web browser (not shown) and application 114 can be hosted on an application server (not shown). Alternatively, the client device 110 includes a local (mobile or desktop) application 114 that provides user interface 112. In some implementations, user interface 112 can communicate with the application 114 via network 130. In some implementations, input data (e.g., sensor data, data to be used as input for a machine learning model, etc.) can be sent to or processed by application 114. Each client device 110 can include an operating system that allows users to generate, view, or edit data (e.g., indication associated with manufacturing equipment 124, corrective actions associated with manufacturing equipment 124, etc.).

Application 114 can be a computer program configured to provide maintenance services, analytics, and predictive technologies performed by one or more evaluation systems (e.g., machine learning models, inference engines, heuristics models, algorithms, physics-based engine, etc.). One or more evaluation systems (e.g., a machine learning model) can be generated by predictive system 160, which is discussed with regards to FIG. 3. In some implementations, to generate a diagnostic report, predictive system 160 can use one or more large language models (LLM) and/or any other type of machine language models trained to perform natural language processing tasks. A diagnostic report can include a listing of possible issues (e.g., root causes) related to particular anomalous data, suggestive corrective actions related to the anomalous data, etc. In some implementations, the listing can be ranked using, for example, a specific criterion.

Corrective action component 116 can be part of application 114 or a separate system (e.g., program, application, etc.). In some implementations, corrective action component 116 receives input data from at least one of server device 150, manufacturing equipment 124, user interface 112, predictive system 160, etc., determines a corrective action based on the input data, and causes the corrective action to be implemented. In some implementations, one or more corrective actions can be triggered automatically in response to the predictive data in a diagnostic report satisfying one or more threshold criteria. For example, certain corrective actions can be listed as permissible to automatically implement if listed in a diagnostic report (e.g., reboot a sensor, change a parameter, etc.). As such, in response to detecting a diagnostic report that lists a permissible corrective action, corrective action component 116 can automatically trigger that corrective action. The corrective actions can be stored in a fault pattern library on data store 140. Each client device 110 can include an operating system that allows users to one or more of generate, view, or edit data (e.g., indication associated with manufacturing equipment 124, corrective actions associated with manufacturing equipment 124, etc.).

Server device 150 can include one or more computing devices (e.g., a server machine, computer, etc.) configured to perform one or more diagnostic related operations. A diagnostic related operation can refer to any operation performed by modules 151-153, such as, for example, data processing, data acquisition, data analysis, troubleshooting, trace matching, event matching, fault identification, anomaly detection, alert generation, selecting and/or performing a corrective action, and so forth. The server device 150 can include sensor control module (SCM) 151, sensor statistic module (SSM) 152, anomaly detection module (ADM) 153, and image acquisition module 154.

The SCM 151 can activate sensors, deactivate sensors, place sensors in an idle state, change settings of the sensors, detect sensor hardware or software problems, and so on. In some implementations, the SCM 151 can keep track of the processing operations performed by the manufacturing equipment 124 and determine which sensors 126 to be sampled for a particular processing (or diagnostic, maintenance, etc.) operation of the manufacturing equipment 124. For example, during a chemical deposition step inside one of the processing chambers, the SCM 151 can sample sensors 126 that are located inside the respective processing chamber but not activate (or sample) sensors 126 located inside the transfer chamber and/or the loading station. The raw data obtained by the SCM 151 can include time series data where a specific sensor 126 captures or generates one or more readings of a detected quantity at a series of times. For example, a pressure sensor can generate N pressure readings P(tᵢ) at time instances t₁, t₂, . . . t_{N}. In some implementations, the raw data obtained by the SCM 151 can include spatial maps at a pre-determined set of spatial locations. For example, an optical reflectivity sensor can determine reflectivity of a film deposited on the surface of a wafer, R(xⱼ, yₗ), at a set (e.g., a two-dimensional set) of spatial locations xⱼ, yₖ, on the surface of the film/substrate. In some implementations, both the time series and the spatial maps raw data can be collected. For example, as the film is being deposited on the wafer, the SCM 151 can collect the reflectivity data from various locations on the surface of the film and at a set of consecutive instances of time, R(tᵢ, xⱼ, yₗ).

SSM 152 can process the raw data obtained by the SCM 151 from the sensors 126 and determine statistics representative of the raw data (referred to as “statistics data”). For example, for each or some of the raw sensor data distributions, the SSM 152 can determine one or more parameters of the distribution, such as a mean, a median, a mode, an upper bound, a lower bound, a variance (or a standard deviation), a skewness (third moment), a kurtosis (fourth moment), or any further moments or cumulants of the data distribution. In some implementations, the SSM 152 can model (e.g., via regression analysis fitting) the raw data with various model distributions (normal distribution, log-normal distribution, binomial distribution, Poisson distribution, Gamma distribution, or any other distribution. In such implementations, the one or more parameters can include an identification of the fitting distribution being used together with the fitting parameters determined by the SSM 152. In some implementations, the SSM 152 can use multiple distributions to fit the raw data from one sensor, e.g., a main distribution and a tail distribution for outlier data points. The parameters of the distributions obtained by the SSM 152 can be sensor-specific. For example, for some sensors a small number of parameters can be determined (mean, median, variance) whereas for some sensor many more (e.g., 10 or 20) moments can be determined.

In some implementations, sensors can be sorted or categorized into one or more groups. Each group can be defined by certain properties or characteristics of the sensors or the data generated by the sensors. For example, the groups can be defined based on sensor settings, sensor output data types, sensor quality, the sub-system the sensor is correlated to (e.g., flow sub-system, temperature sub-system, pressure sub-system, etc.), etc. The sensors can be grouped from one of more process chambers of manufacturing equipment 124, or from process chambers of multiple manufacturing tools (e.g., manufacturing equipment or components thereof). In some implementations, one or more algorithms to categorize sensors into one or more specific groups. For example, a detection algorithm can be configured to correlate each sensor to one or more predefined groups based on one or more predefined criterion.

ADM 153 can identify anomalies in the sensor data that could be indicative of a fault or defect related to a sensor, a sensor group, a component of manufacturing equipment 124, etc. In some implementations, ADM 153 can pre-process, reduce the dimensionality of the sensor statistics, process the reduced representations of statistics by multiple anomaly detection models, normalize, and/or process using a detector neural network to determine one or more anomaly scores. At least some of the listed operations can include machine learning. In some implementations, ADM 153 can one or more detection techniques, such as, for example, statistical anomaly detection techniques (e.g., Z-score, Tukey's range test, Grubb's test, etc.), ensemble techniques (e.g., the Anomaly Detection Ensemble (ADE) system, feature bagging techniques, score normalization techniques, etc.), fuzzy logic-based outlier detection techniques, Bayesian networks, hidden Markov models (HMMs), a Fourier transform method, a trace analysis method that generates adaptive “guardbands” on certain sensors (referred to as a “Guardband system”), an anomaly detection neural network (ADN), or any other type of anomaly detection techniques. One or more machine learning models configured to perform operations related to one or more detection techniques of ADM 113 can be generated by the predictive system 160 or other types of predictive systems. In some implementations, predictive system 160 can generate different trained machine learning models, each configured to perform multiple different types of detection techniques.

Although shown as modules of server device 150, each module 151-153 can be included in one or more other computing devices, such as a rackmount server, a router computer, a server computer, a personal computer, a mainframe computer, a laptop computer, a tablet computer, a desktop computer, a GPU, an ASIC, etc. Each module 151-153 can execute instructions to perform any one or more of the methodologies and/or implementations described herein. The instructions can be stored on a computer readable storage medium, which can include the main memory, static memory, secondary storage and/or processing device (during execution of the instructions).

Data store 140 can be a memory (e.g., random access memory), a drive (e.g., a hard drive, a flash drive), a database system, or another type of component or device capable of storing data. Data store 140 can include multiple storage components (e.g., multiple drives or multiple databases) that can span multiple computing devices (e.g., multiple server computers). The data store 140 can store data associated with processing a substrate at manufacturing equipment 124. For example, data store 140 can store data collected by sensors 126 at manufacturing equipment 124 before, during, or after a substrate process (referred to as process data). Process data can refer to historical process data (e.g., process data generated for a prior substrate processed at the manufacturing system) and/or current process data (e.g., process data generated for a current substrate processed at the manufacturing system). Data store can also store spectral data or non-spectral data associated with a portion of a substrate processed at manufacturing equipment 124. Spectral data can include historical spectral data and/or current spectral data.

Data store 140 can also store contextual data associated with one or more substrates processed at the manufacturing system. Contextual data can include a recipe name, recipe step number, preventive maintenance indicator, operator, etc. Contextual data can refer to historical contextual data (e.g., contextual data associated with a prior process performed for a prior substrate) and/or current process data (e.g., contextual data associated with current process or a future process to be performed for a prior substrate). The contextual data can further include identify sensors that are associated with a particular sub-system of a process chamber.

Data store 140 can also store task data. Task data can include one or more sets of operations to be performed for the substrate during a deposition process and can include one or more settings associated with each operation. For example, task data for a deposition process can include a temperature setting for a process chamber, a pressure setting for a process chamber, a flow rate setting for a precursor for a material of a film deposited on a substrate, etc. In another example, task data can include controlling pressure at a defined pressure point for the flow value. Task data can refer to historical task data (e.g., task data associated with a prior process performed for a prior substrate) and/or current task data (e.g., task data associated with current process or a future process to be performed for a substrate).

In some implementations, data store 140 can store statistics data. Statistics data can include statistics representative of the raw data, generated by SSM 152, e.g., mean data (average), range data, standard deviation data, maximum and minimum data, median data, mode data, etc. Mean data can include a measured averages of two or more values. For example, mean data can be used to determine the average heater temperature, the process chamber pressure, the average flowrate of a gas, etc., during a step(s), a specific time duration, an entire process recipe, etc. Range data can include the middle observation in a set of data (e.g., a median temperature during a step). Range data can include the difference between a maximum value and a minimum value of a set of values (e.g. the range of the heater pressure during a process recipe). The standard deviation is measure of the amount of variation or dispersion of a set of values.

In some implementations, data store 140 can store specific-knowledge data. Specific-knowledge data can include unique, valuable, and/or proprietary data related to a certain topic, item, and/or organization. Specific-knowledge data can include data from one or more public or private data sources, such as, for example, research papers, technical support tickets, user manuals, tech bulletins, service cases, reports, transcripts, guides, technical libraries, and so forth. In instances where the specific knowledge data is private, access to the specific-knowledge data can be restricted to, for example, users or systems with pre-approved access to the specific knowledge data, users or systems with proper credentials (e.g., a username and password, a cryptographic key, etc.), etc.

In some implementations, data store 140 can be configured to store data that is not accessible to a user of the manufacturing system. For example, process data, spectral data, contextual data, etc. obtained for a substrate being processed at the manufacturing system is not accessible to a user (e.g., an operator) of the manufacturing system. In some implementations, all data stored at data store 140 can be inaccessible by the user of the manufacturing system. In other or similar implementations, a portion of data stored at data store 140 can be inaccessible by the user while another portion of data stored at data store 140 can be accessible by the user. In some implementations, one or more portions of data stored at data store 140 can be encrypted using an encryption mechanism that is unknown to the user (e.g., data is encrypted using a private encryption key). In other or similar implementations, data store 140 can include multiple data stores where data that is inaccessible to the user is stored in one or more first data stores and data that is accessible to the user is stored in one or more second data stores.

The server device 150, client device 110, manufacturing equipment 124, sensors 126, predictive system 160, metrology equipment 128 and data store 140 can be coupled to each other via a network 130. In some implementations, network 130 is a public network that provides server device 150 and client device 110 with access to predictive system 160, data store 140, manufacturing equipment 124, manufacturing equipment 128, and other publicly available computing devices. In some implementations, network 130 is a private network that provides server device 150 and client device 110 access to manufacturing equipment 124, data store 140, predictive system 160, manufacturing equipment 128, and other privately available computing devices. Network 130 can include one or more wide area networks (WANs), local area networks (LANs), wired networks (e.g., Ethernet network), wireless networks (e.g., an 802.11 network or a Wi-Fi network), cellular networks (e.g., a Long-Term Evolution (LTE) network), routers, hubs, switches, server computers, cloud computing networks, and/or a combination thereof.

In implementations, a “user” can be represented as a single individual. However, other implementations of the disclosure encompass a “user” being an entity controlled by a plurality of users and/or an automated source. For example, a set of individual users federated as a group of administrators can be considered a “user.”

FIG. 2 is a top schematic view of an example manufacturing system 200, according to aspects of the present disclosure. Manufacturing system 200 can perform one or more processes on a substrate 202. Substrate 202 can be any suitably rigid, fixed-dimension, planar article, such as, e.g., a silicon-containing disc or wafer, a patterned wafer, a glass plate, or the like, suitable for fabricating electronic devices or circuit components thereon.

Manufacturing system 200 can include a process tool 204 and a factory interface 206 coupled to process tool 204. Process tool 204 can include a housing 208 having a transfer chamber 210 therein. Transfer chamber 210 can include one or more process chambers (also referred to as processing chambers) 214, 216, 218 disposed therearound and coupled thereto. Process chambers 214, 216, 218 can be coupled to transfer chamber 210 through respective ports, such as slit valves or the like. Transfer chamber 210 can also include a transfer chamber robot 212 configured to transfer substrate 202 between process chambers 214, 216, 218, load lock 220, etc. Transfer chamber robot 212 can include one or multiple arms where each arm includes one or more end effectors at the end of each arm. The end effector can be configured to handle particular objects, such as wafers, sensor discs, sensor tools, etc.

Process chambers 214, 216, 218 can be adapted to carry out any number of processes on substrates 202. A same or different substrate process can take place in each processing chamber 214, 216, 218. A substrate process can include atomic layer deposition (ALD), physical vapor deposition (PVD), chemical vapor deposition (CVD), etching, annealing, curing, pre-cleaning, metal or metal oxide removal, or the like. Other processes can be carried out on substrates therein. Process chambers 214, 216, 218 can each include one or more sensors configured to capture data for substrate 202 before, after, or during a substrate process. For example, the one or more sensors can be configured to capture spectral data and/or non-spectral data for a portion of substrate 202 during a substrate process. In other or similar implementations, the one or more sensors can be configured to capture data associated with the environment within process chamber 214, 216, 218 before, after, or during the substrate process. For example, the one or more sensors can be configured to capture data associated with a temperature, a pressure, a gas concentration, etc. of the environment within process chamber 214, 216, 218 during the substrate process.

In some implementations, metrology equipment (not shown) can be located within the process tool. In other implementations, metrology equipment (not shown) can be located within one or more process chambers 214, 216, 218. In some implementations, the substrate can be placed onto metrology equipment using transfer chamber robot 212. In other implementations, the metrology equipment can be part of the substrate support assembly (not shown). Metrology equipment can provide metrology data associated with substrates processed by manufacturing equipment 124. The metrology data can include a value of film property data (e.g., wafer spatial film properties), dimensions (e.g., thickness, height, etc.), dielectric constant, dopant concentration, density, defects, etc. In some implementations, the metrology data can further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data can be of a finished or semi-finished product. The metrology data can be different for each substrate. Metrology data can be generated using, for example, reflectometry techniques, ellipsometry techniques, TEM techniques, and so forth.

A load lock 220 can also be coupled to housing 208 and transfer chamber 210. Load lock 220 can be configured to interface with, and be coupled to, transfer chamber 210 on one side and factory interface 206. Load lock 220 can have an environmentally-controlled atmosphere that can be changed from a vacuum environment (wherein substrates can be transferred to and from transfer chamber 210) to an at or near atmospheric-pressure inert-gas environment (wherein substrates can be transferred to and from factory interface 206) in some implementations. Factory interface 206 can be any suitable enclosure, such as, e.g., an Equipment Front End Module (EFEM). Factory interface 206 can be configured to receive substrates 202 from substrate carriers 222 (e.g., Front Opening Unified Pods (FOUPs)) docked at various load ports 224 of factory interface 206. A factory interface robot 226 (shown dotted) can be configured to transfer substrates 202 between carriers (also referred to as containers) 222 and load lock 220. Carriers 222 can be a substrate storage carrier or a replacement part storage carrier.

Manufacturing system 200 can also be connected to a client device (e.g., client device 110, not shown) that is configured to provide information regarding manufacturing system 200 to a user (e.g., an operator). In some implementations, the client device can provide information to a user of manufacturing system 200 via one or more graphical user interfaces (GUIs). For example, the client device can provide information regarding a target thickness profile for a film to be deposited on a surface of a substrate 202 during a deposition process performed at a process chamber 214, 216, 218 via a GUI. The client device can also provide information regarding maintenance services, analytics, and predictive technologies in accordance with implementations described herein.

Manufacturing system 200 can also include a system controller 228. System controller 228 can be and/or include a computing device such as a personal computer, a server computer, a programmable logic controller (PLC), a microcontroller, and so on. System controller 228 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 228 can include a data storage device (e.g., one or more disk drives and/or solid state drives), a main memory, a static memory, a network interface, and/or other components. System controller 228 can execute instructions to perform any one or more of the methodologies and/or implementations described herein. In some implementations, system controller 228 can execute instructions to perform one or more operations at manufacturing system 200 in accordance with a process recipe. The instructions can be stored on a computer readable storage medium, which can include the main memory, static memory, secondary storage and/or processing device (during execution of the instructions).

System controller 228 can receive data from sensors (e.g., sensors 126, now shown) included on or within various portions of manufacturing system 200 (e.g., processing chambers 214, 216, 218, transfer chamber 210, load lock 220, etc.). In some implementations, data received by the system controller 228 can include spectral data and/or non-spectral data for a portion of substrate 202. In other or similar implementations, data received by the system controller 228 can include data associated with processing substrate 202 at processing chamber 214, 216, 218, as described previously. For purposes of the present description, system controller 228 is described as receiving data from sensors included within process chambers 214, 216, 218. However, system controller 228 can receive data from any portion of manufacturing system 200 and can use data received from the portion in accordance with implementations described herein. In an illustrative example, system controller 228 can receive data from one or more sensors for process chamber 214, 216, 218 before, after, or during a substrate process at the process chamber 214, 216, 218. Data received from sensors of the various portions of manufacturing system 200 can be stored in a data store 250. Data store 250 can be included as a component within system controller 228 or can be a separate component from system controller 228. In some implementations, data store 250 can be data store 140 described with respect to FIG. 1.

FIG. 3 depicts an illustrative predictive architecture 300, according to aspects of the present disclosure. In some implementations, predictive architecture 300 include predictive system 160, network 130, and data store 310 (which can be similar to the same as data store 140). Predictive system 160 can use a model (e.g., model 190) to generate one or more diagnostic reports, to generate one or more knowledge-based reports, detect and/or identify one or more root causes related to an anomaly, determine a corrective action related to an anomaly, etc.

Multiple models can be generated (e.g., trained) and configured for use by application 114, predictive server 195, etc. In some implementations, each model 190 can be referred to as a “predictive subsystem”. In some implementations, predictive system 160 can include predictive server 112, server machines 170 and 180, and predictive server 195. The predictive server 160, server machine 170, server machine 180, and predictive server 195 can each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc.

Server machine 170 includes a training set generator 172 that is capable of generating training data sets (e.g., a set of data inputs and a set of target outputs) to train, validate, and/or test a machine learning model 190. Machine learning model 190 can be any algorithmic model capable of learning from data. In some implementations, machine learning model 190 can be a predictive model. In some implementations, the data set generator 172 can partition the training data into a training set, a validating set, and a testing set, which can be stored, as part of the training statistics 312, in the training data store 310. Training statistics 312 which can be accessible to the computing device predictive system 160 directly or via network 130. In some implementations, the predictive system 160 generates multiple sets of training data.

Server machine 180 can include a training engine 182, a validation engine 184, a selection engine 185, and/or a testing engine 186. An engine can refer to hardware (e.g., circuitry, dedicated logic, programmable logic, microcode, processing device, etc.), software (such as instructions run on a processing device, a general-purpose computer system, or a dedicated machine), firmware, microcode, or a combination thereof. Training engine 182 can be capable of training one or more machine learning model 190. Machine learning model 190 can refer to the model artifact that is created by the training engine 182 using the training data (also referred to herein as a training set) that includes training inputs and corresponding target outputs (correct answers for respective training inputs). The training engine 182 can find patterns in the training data that map the training input to the target output (the answer to be predicted), and provide the machine learning model 190 that captures these patterns. The machine learning model 190 can use one or more of a statistical modelling, support vector machine (SVM), Radial Basis Function (RBF), clustering, supervised machine learning, semi-supervised machine learning, unsupervised machine learning, k-nearest neighbor algorithm (k-NN), linear regression, random forest, neural network (e.g., artificial neural network), etc.

One type of machine learning model that can be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities can be addressed, at lower layers, on top of which a multi-layer perceptron is commonly appended, mapping top layer features extracted by the convolutional layers to decisions (e.g., classification outputs). Deep learning is a class of machine learning algorithms that use a cascade of multiple layers of nonlinear processing units for feature extraction and transformation. Each successive layer uses the output from the previous layer as input. Deep neural networks can learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. In a plasma process tuning, for example, the raw input can be process result profiles (e.g., thickness profiles indicative of one or more thickness values across a surface of a substrate); the second layer can compose feature data associated with a status of one or more zones of controlled elements of a plasma process system (e.g., orientation of zones, plasma exposure duration, etc.); the third layer can include a starting recipe (e.g., a recipe used as a starting point for determining an updated process recipe the process a substrate to generate a process result the meets threshold criteria). Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs can be that of the network and can be the number of hidden layers plus one. For recurrent neural networks, in which a signal can propagate through a layer more than once, the CAP depth is potentially unlimited.

In some implementations, one or more machine learning models can be a large language model (LLM). An LLM is a type of artificial intelligence (e.g., machine learning) model designed to understand and generate human-like text. LLMs can perform natural language processing tasks such as language translation, text summarization, question answering, etc. LLM 160 can be built on deep learning architectures, such as transformer models. In some implementations, LLM 160 can be generated through supervised learning, during which the LLM is trained on large datasets of text. The text can be gathered from various sources, such as books, articles, websites, digital libraries, and so forth. A text dataset can be used to pre-train an LLM on a language modeling task where the LLM learns to predict the next word in a sequence of text given the previous words. This pre-training phase can be used to develop, for the LLM, a deep understanding of language patterns and semantics. After pre-training, the LLM can be fine-tuned on specific tasks to specialize its capabilities. During fine-tuning, the LLM can be exposed to examples of the target task, such as text classification or language translation, corresponding labels or target outputs, etc. In some implementations, the LLM can adjust one or more parameters to minimize the difference between predictions and true outputs. The adjusting can be performed using iterative optimization techniques, such as, for example, gradient descent. The adjusting process can enable the LLM to adapt pre-learned knowledge to the nuances of the target task, making it more effective in real-world applications. In some implementations, the LLM can be used to generate one or more diagnostic reports and/or knowledge-based reports. This will be described in detail below.

In some implementations, one or more machine learning models can be a recurrent neural network (RNN). An RNN is a type of neural network that includes a memory to enable the neural network to capture temporal dependencies. An RNN is able to learn input-output mappings that depend on both a current input and past inputs. The RNN will address past and future flow rate measurements and make predictions based on this continuous metrology information. RNNs can be trained using a training dataset to generate a fixed number of outputs (e.g., to determine a set of substrate processing rates, determine modification to a substrate process recipe). One type of RNN that can be used is a long short term memory (LSTM) neural network.

Training of a neural network can be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset.

A training dataset containing hundreds, thousands, tens of thousands, hundreds of thousands or more sensor data and/or process result data (e.g., metrology data such as one or more thickness profiles associated with the sensor data) can be used to form a training dataset.

To effectuate training, processing logic can input the training dataset(s) into one or more untrained machine learning models. Prior to inputting a first input into a machine learning model, the machine learning model can be initialized. Processing logic trains the untrained machine learning model(s) based on the training dataset(s) to generate one or more trained machine learning models that perform various operations as set forth above. Training can be performed by inputting one or more of the sensor data into the machine learning model one at a time.

The machine learning model processes the input to generate an output. An artificial neural network includes an input layer that consists of values in a data point. The next layer is called a hidden layer, and nodes at the hidden layer each receive one or more of the input values. Each node contains parameters (e.g., weights) to apply to the input values. Each node therefore essentially inputs the input values into a multivariate function (e.g., a non-linear mathematical transformation) to produce an output value. A next layer can be another hidden layer or an output layer. In either case, the nodes at the next layer receive the output values from the nodes at the previous layer, and each node applies weights to those values and then generates its own output value. This can be performed at each layer. A final layer is the output layer, where there is one node for each class, prediction and/or output that the machine learning model can produce.

Accordingly, the output can include one or more predictions or inferences. In some implementations, an output prediction or inference can include one or more predictions relating to detecting a root cause related to a particle event, one or more corrective action to take in response to the particle event, etc. In some implementations, an output prediction or inference can include one or more predictions of diagnostic data corrective action data, etc. Processing logic determines an error (i.e., a classification error) based on the differences between the output (e.g., predictions or inferences) of the machine learning model and target labels associated with the input training data. Processing logic adjusts weights of one or more nodes in the machine learning model based on the error. An error term or delta can be determined for each node in the artificial neural network. Based on this error, the artificial neural network adjusts one or more of its parameters for one or more of its nodes (the weights for one or more inputs of a node). Parameters can be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters can include adjusting the weights assigned to each of the inputs for one or more neurons at one or more layers in the artificial neural network.

After one or more rounds of training, processing logic can determine whether a stopping criterion has been met. A stopping criterion can be a target level of accuracy, a target number of processed images from the training dataset, a target amount of change to parameters over one or more previous data points, a combination thereof and/or other criteria. In one implementation, the stopping criteria is met when at least a minimum number of data points have been processed and at least a threshold accuracy is achieved. The threshold accuracy can be, for example, 70%, 80% or 90% accuracy. In one implementation, the stopping criterion is met if accuracy of the machine learning model has stopped improving. If the stopping criterion has not been met, further training is performed. If the stopping criterion has been met, training can be complete. Once the machine learning model is trained, a reserved portion of the training dataset can be used to test the model.

Once one or more trained machine learning models 190 are generated, they can be stored in predictive server 195 as predictive component 197 or as a component of predictive component 197.

The validation engine 184 can be capable of validating machine learning model 190 using a corresponding set of features of a validation set from training set generator 172. Once the model parameters have been optimized, model validation can be performed to determine whether the model has improved and to determine a current accuracy of the deep learning model. The validation engine 184 can determine an accuracy of machine learning model 190 based on the corresponding sets of features of the validation set. The validation engine 184 can discard a trained machine learning model 190 that has an accuracy that does not meet a threshold accuracy. In some implementations, the selection engine 185 can be capable of selecting a trained machine learning model 190 that has an accuracy that meets a threshold accuracy. In some implementations, the selection engine 185 can be capable of selecting the trained machine learning model 190 that has the highest accuracy of the trained machine learning models 190.

The testing engine 186 can be capable of testing a trained machine learning model 190 using a corresponding set of features of a testing set from data set generator 172. For example, a first trained machine learning model 190 that was trained using a first set of features of the training set can be tested using the first set of features of the testing set. The testing engine 186 can determine a trained machine learning model 190 that has the highest accuracy of all of the trained machine learning models based on the testing sets.

As described in detail below, predictive server 195 includes a predictive component 197 that is capable of providing diagnostic reports and/or knowledge-based reports that include predictive data reflect issue data (e.g., root cause data), corrective action data, etc. and running trained machine learning model 190 on data items such as input prompts to obtain one or more outputs.

It should be noted that in some other implementations, the functions of server machines 170 and 180, as well as predictive server 195, can be provided by a fewer number of machines. For example, in some implementations, server machines 170 and 180 can be integrated into a single machine, while in some other or similar implementations, server machines 170 and 180, as well as predictive server 195, can be integrated into a single machine.

In general, functions described in one implementation as being performed by server machine 170, server machine 180, and/or predictive server 195 can also be performed on client device 110. In addition, the functionality attributed to a particular component can be performed by different or multiple components operating together.

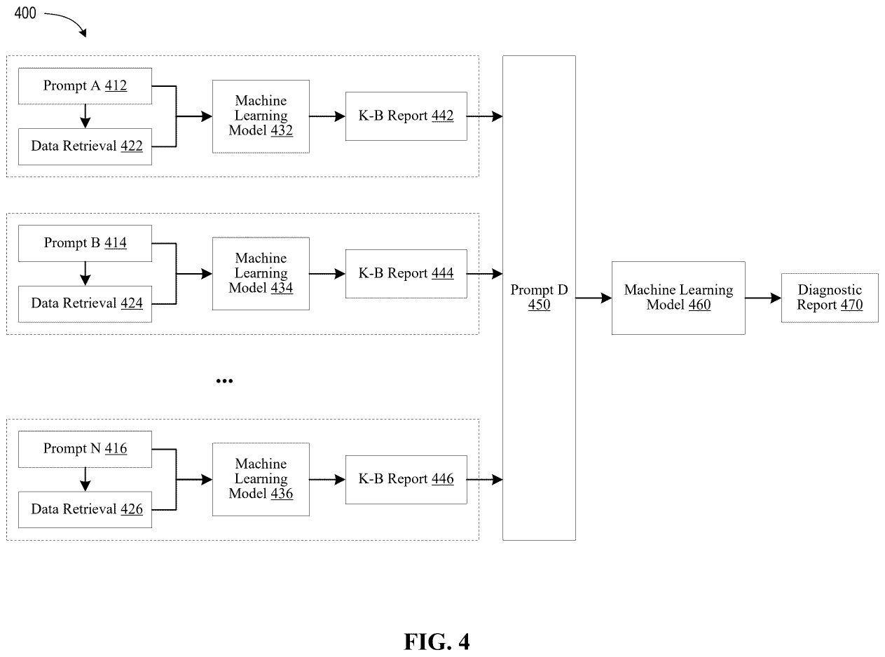

FIG. 4 is a diagram of a framework 400 for applying a machine learning model to generate a diagnostic report, in accordance with some implementations of the present disclosure. For each anomaly detected in manufacturing equipment 124, a set of prompts A-N 412-416 (e.g., questions or statements) are automatically generated. The set of prompts A-N 412-416 can be generated based on, for example, the type of anomaly, the sub-system type that generated the anomaly, the sensor type related to the anomaly, a predetermined listing, etc. In some implementations, each prompt A-N 412-416 can be structured to ask, from a machine learning model, a specific question. In an illustrative example, the questions can include, for example, “were similar inspections performed in response to detecting this type of anomaly,” “which components have been replaced for the identified anomaly,” “which corrective actions have fixed this type of anomaly,” etc. In some implementations, each of prompts A-N 412-416 can further include one or more of a task(s), an instruction(s), a desired format, etc.

Each prompt A-N 412-416 (e.g., each predetermined question or statement) can be correlated to a specific database (e.g., from datastore 140) from which data retrieval operations 422-426 can obtain corresponding data (e.g., specific-knowledge data). In an illustrative example, data retrieval operation 422 can obtain a set of technical support tickets, data retrieval operation 424 can obtain a set of data from a manufacturing equipment technical library, and data retrieval operation 426 can obtain a set of previous service cases related to the sub-system of the detected anomaly. Each respective prompt A-N 412-416 and corresponding retrieved data pair can be provided, as input, to a corresponding machine learning model (e.g., machine learning model 432-436). In some implementations, machine learning models 432-436 can each be an LLM or any other type of machine language model trained to perform natural language processing tasks, such as those described with reference to model 190. In some implementations, each of machine learning models 432-436 can be the same machine learning model. In some implementations, one or more of the machine learning models 432-436 can be different from each other. In some implementations, machine learning models 432-436 can be trained as discussed in relation to training model 190.

In some implementations, each of machine learning models 432-436 can be supported by a prompt subsystem used to provide the prompt and retrieved data pair to the respective machine learning model 432-436. The prompt sub-system can be a part of application 114 of each respective machine learning model 432-436, etc. The prompt subsystem can enable access to each respective machine learning model 432-436. The prompt subsystem can be configured to perform automated identification of, and facilitate retrieval of, relevant and timely contextual information for efficient and accurate processing of prompts by machine learning model 432-436. Using network 130 (or another network), the prompt subsystem can be in communication with one or more of client device 110, manufacturing equipment 124, data store 140, predictive system 160, server device 150, etc. In some implementations, communications between the prompt subsystem and the machine learning models 432-436 can be facilitated by an application programming interface (API). In some implementations, the API translates prompts generated by the prompt subsystem into unstructured natural-language format and, conversely, translates responses received from the machine learning model 432-436 (and/or machine learning model 460) into any suitable form (e.g., including any structured proprietary format as may be used by the prompt subsystem). Similarly, the API can support instructions that can be used to communicate data requests to client device 102, manufacturing equipment 124, data store 140, predictive system 160, and/or server device 150, and formats of data received from such components.

The prompt subsystem can include (or can have access to) instructions stored on one or more tangible, machine-readable storage media of a computing device (e.g., the client device 110, server device 150, and/or predictive system 160) and executable by one or more processing devices of the computing device. In some implementations, the prompt subsystem is implemented on a single machine. In some implementations, the prompt subsystem is a combination of a client component and a server component. In some implementations, the prompt subsystem is executed entirely on the predictive system (e.g., executed automatically). Alternatively, some portion (or all of) of the prompt subsystem can be executed on a client device 110 and/or server device 150, while another portion of the prompt subsystem can be executed on a different component (e.g., predictive subsystem 160).

Each machine learning model 432-436 can generate, as output, a respective knowledge-based report 442-446. Each of the received outputs can be referred to as a knowledge-based report. In some implementations, the knowledge-based reports 442-446 can include predictive data indicative of one or more answers to the respective prompt in view of the retrieved specific-knowledge data. Thus, knowledge-based report 442-446 can be source informed answers. In some implementations, the knowledge-based reports 442-446 can include data indicative of one or more issues related to an identified anomaly, one or more corrective actions that resolved the identified anomaly, one or more part numbers, one or more citations or sources, one or more reprinted sections of text, etc.

The knowledge-based reports 442-446 can be organized into a single structured prompt D 450. In particular, knowledge-based reports 442-446 can be organized into a specified structure to enhance coherence and relevance in querying machine learning model 460. Prompt D 450 can include one or more tasks (e.g., generate a diagnostic report that identities one or more issues of the provided anomaly and one or more corrective actions to address the anomaly), one or more instructions (e.g., scrub sensitive or customer data from the diagnostic report, sort the corrective actions by prioritizing inspections before replacing components, etc.), a request for a desired format, the data from knowledge-based reports 442-446, etc. The data from outputs 442-446 can be raw, formatted, partial, etc. Prompt D 450 can then be provided to machine learning model 460 via, for example, the prompt subsystem. Machine learning model 460 can then generate diagnostic report 470. In an illustrative example, the diagnostic report 470 can include a problem statement, a scrubbed plot (e.g., no axis, no customer intellectual property, etc.) of the sensor data related to the anomaly, predictive data identifying the issue, one or more recommendations (e.g., a recommended corrective action), one or more recent actions performed to address the identified anomaly, and a listing of similar anomalies.

In some implementations, machine learning model 460 can be the same as any of machine learning models 432-436. In some implementations, machine learning model 460 can be the different than any of machine learning models 432-436. In some implementations, machine learning model 460 can be trained as discussed in relation to training model 190. In some implementations, the diagnostic report 460 can be sent to client device 110, an email address, an external computer, etc.

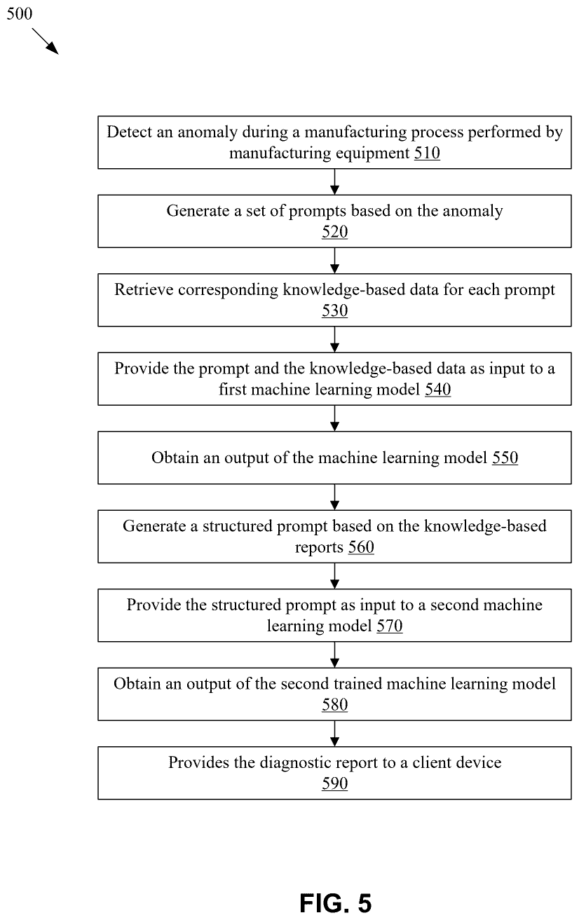

FIG. 5 is a flow diagram of method 500 for generating a diagnostic report, in accordance with some implementations of the present disclosure. In some implementations, method 500 is performed by processing logic that includes hardware (e.g., circuitry, dedicated logic, programmable logic, microcode, processing device, etc.), software (such as instructions run on a processing device, a general-purpose computer system, or a dedicated machine), firmware, microcode, or a combination thereof. In some implementations, method 500 is performed, at least in part, by predictive system 160 and/or client device 110. In some implementations, a non-transitory storage medium stores instructions that when executed by a processing device (e.g., of predictive system 160, of predictive server 195, etc.) cause the processing device to perform one or more of method 500.

For simplicity of explanation, method 500 is depicted and described as a series of operations. However, operations in accordance with this disclosure can occur in various orders and/or concurrently and with other operations not presented and described herein. Furthermore, in some implementations, not all illustrated operations are performed to implement method 500 in accordance with the disclosed subject matter. In addition, those skilled in the art will understand and appreciate that method 500 could alternatively be represented as a series of interrelated states via a state diagram or events.

At operation 510, the processing logic detects an anomaly during a manufacturing process performed by manufacturing equipment 124. In some implementations, ADM module 153 can issue an alert in response to detecting sensor data satisfying a threshold criterion (e.g., trace data exceeding a threshold value).

At operation 520, the processing logic generates a set of prompts based on the anomaly. The set of prompts can be generated based on, for example, the type of anomaly, the sub-system type that generated the anomaly, the sensor type related to the anomaly, a predetermined listing, etc.

At operation 530, the processing logic retrieves corresponding knowledge-based data for each prompt. The knowledge-based data can be retrieved from, for example, datastore 140.

At operation 540, the processing logic provides the prompt and the knowledge-based data as input to a first machine learning model. The first machine-learning model can be, for example, an LLM. Each prompt and knowledge-based data pair can be provided to the first machine learning model individually (e.g., one at a time to obtain a respective output).

At operation 550, the processing logic obtains an output of the first machine learning model. The output of the first machine learning model includes a set of knowledge-based reports. The knowledge-based reports can include predictive data indicative of one or more answers to the respective prompt in view of the retrieved specific-knowledge data.

At operation 560, the processing logic generates a structured prompt based on the knowledge-based reports. The structured prompt can be organized into a specified structure to enhance coherence and relevance. The structured prompt can include one or more of a tasks, one or more instructions, a request for a desired format, the data from the knowledge-based reports, etc.

At operation 570, the processing logic provides the structured prompt as input to a second machine learning model. The second machine learning model may be the same as, or different from, the first machine learning model.

At operation 580, the processing logic obtains an output of the second trained machine learning model. The output of the second trained machine learning model includes a diagnostic report associated with the anomaly.

At operation 590, the processing logic provides the diagnostic report to a client device. For example, the processing logic can send the diagnostic report to application 114 of client device 110.

In some implementations, the processing logic can automatic trigger a corrective action based on the diagnostic report (e.g., via corrective component 116). For example, certain corrective actions can be listed as permissible to automatically implement if listed in the diagnostic report (e.g., reboot a sensor, change a parameter, etc.). As such, in response to detecting that the diagnostic report lists a permissible corrective action, the processing logic can automatically trigger that corrective action.

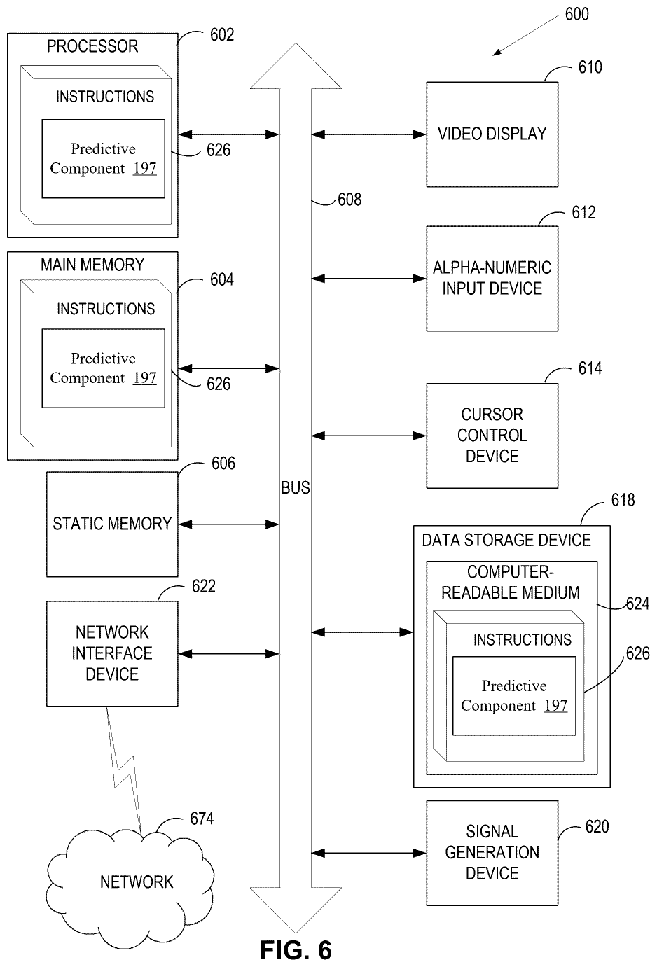

FIG. 6 is a block diagram illustrating a computer system 600, according to certain implementations. In some implementations, computer system 600 can be connected (e.g., via a network, such as a Local Area Network (LAN), an intranet, an extranet, or the Internet) to other computer systems. Computer system 600 can operate in the capacity of a server or a client computer in a client-server environment, or as a peer computer in a peer-to-peer or distributed network environment. Computer system 600 can be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 600 can include a processing device 602, a volatile memory 604 (e.g., Random Access Memory (RAM)), a non-volatile memory 606 (e.g., Read-Only Memory (ROM) or Electrically-Erasable Programmable ROM (EEPROM)), and a data storage device 616, which can communicate with each other via a bus 608.

Processing device 602 can be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 600 can further include a network interface device 622 (e.g., coupled to network 674). Computer system 600 also can include a video display unit 610 (e.g., an LCD), an alphanumeric input device 612 (e.g., a keyboard), a cursor control device 614 (e.g., a mouse), and a signal generation device 620.

In some implementations, data storage device 616 can include a non-transitory computer-readable storage medium 624 on which can store instructions 626 encoding any one or more of the methods or functions described herein, including instructions encoding components of FIG. 1 (e.g., predictive component 197, application 114, etc.) and for implementing methods described herein.

Instructions 626 can also reside, completely or partially, within volatile memory 604 and/or within processing device 602 during execution thereof by computer system 600, hence, volatile memory 604 and processing device 602 can also constitute machine-readable storage media.

While computer-readable storage medium 624 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein can be implemented by discrete hardware components or can be integrated in the functionality of other hardware components such as ASICS, FPGAs, DSPs or similar devices. In addition, the methods, components, and features can be implemented by firmware modules or functional circuitry within hardware devices. Further, the methods, components, and features can be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and cannot have an ordinal meaning according to their numerical designation.

Examples described herein also relate to an apparatus for performing the methods described herein. This apparatus can be specially constructed for performing the methods described herein, or it can include a general purpose computer system selectively programmed by a computer program stored in the computer system. Such a computer program can be stored in a computer-readable tangible storage medium.

The methods and illustrative examples described herein are not inherently related to any particular computer or other apparatus. Various general purpose systems can be used in accordance with the teachings described herein, or it can prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A method, comprising:
detecting, by a processing device, an anomaly that occurred during a manufacturing process performed by a substrate processing system;
generating a set of prompts based on the anomaly, wherein each prompt is correlated to specific data obtained from one or more datastores;
providing, individually as input to a first trained machine learning model, each prompt along with the respective specific data;
obtaining, for each prompt, a respective output of the first trained machine learning model;
generating a structured prompt based on respective outputs;
providing the structured prompt as input to a second trained machine learning model; and
obtaining an output of the second trained machine learning model, the output of the second trained machine learning model comprising a diagnostic report associated with the anomaly.

2. The method of claim 1, wherein the diagnostic report comprises at least one predictive corrective action to address the anomaly.

3. The method of claim 1, further comprising:
performing a corrective action based on the diagnostic report.

4. The method of claim 1, wherein the first machine-learning model is a large language model (LLM).

5. The method of claim 1, wherein the first machine learning model is the same as the second machine learning model.

6. The method of claim 1, wherein the structured prompt comprises one or more tasks, one or more instructions, a desired format, and data from each respective output.

7. The method of claim 1, further comprising:
providing the diagnostic report to a client device.

8. A system, comprising:
a memory device; and
a processing device, operatively coupled to the memory device, to perform operations comprising:
detecting an anomaly that occurred during a manufacturing process performed by a substrate processing system;
generating a set of prompts based on the anomaly, wherein each prompt is correlated to specific data obtained from one or more datastores;
providing, individually as input to a first trained machine learning model, each prompt along with the respective specific data;
obtaining, for each prompt, a respective output of the first trained machine learning model;
generating a structured prompt based on respective outputs;
providing the structured prompt as input to a second trained machine learning model; and
obtaining an output of the second trained machine learning model, the output of the second trained machine learning model comprising a diagnostic report associated with the anomaly.

9. The system of claim 8, wherein the diagnostic report comprises at least one predictive corrective action to address the anomaly.

10. The system of claim 8, wherein the operations further comprise:
performing a corrective action based on the diagnostic report.

11. The system of claim 8, wherein the first machine-learning model is a large language model (LLM).

12. The system of claim 8, wherein the first machine learning model is the same as the second machine learning model.

13. The system of claim 8, wherein the structured prompt comprises one or more tasks, one or more instructions, a desired format, and data from each respective output.

14. The system of claim 8, wherein the operations further comprise:
providing the diagnostic report to a client device.

15. A non-transitory computer-readable storage medium comprising instructions that, when executed by a processing device operatively coupled to a memory, performs operations comprising:
detecting an anomaly that occurred during a manufacturing process performed by a substrate processing system;
generating a set of prompts based on the anomaly, wherein each prompt is correlated to specific data obtained from one or more datastores;
providing, individually as input to a first trained machine learning model, each prompt along with the respective specific data;
obtaining, for each prompt, a respective output of the first trained machine learning model;
generating a structured prompt based on respective outputs;
providing the structured prompt as input to a second trained machine learning model; and
obtaining an output of the second trained machine learning model, the output of the second trained machine learning model comprising a diagnostic report associated with the anomaly.

16. The non-transitory computer-readable storage medium of claim 15, wherein the diagnostic report comprises at least one predictive corrective action to address the anomaly.

17. The non-transitory computer-readable storage medium of claim 15, wherein the operations further comprise:
performing a corrective action based on the diagnostic report.

18. The non-transitory computer-readable storage medium of claim 15, wherein the first machine-learning model is a large language model (LLM).

19. The non-transitory computer-readable storage medium of claim 15, wherein the first machine learning model is the same as the second machine learning model.

20. The non-transitory computer-readable storage medium of claim 15, wherein the structured prompt comprises one or more tasks, one or more instructions, a desired format, and data from each respective output.
